(19) United States
(12) Patent Application Publication
(10) Pub. No.: US 2017/0084477 A1
(43) Pub. Date: Mar. 23, 2017

(54) SUBSTRATE SUPPORT UNIT AND SUBSTRATE TREATMENT APPARATUS COMPRISING THE SAME

(71) Applicant: SAMSUNG ELECTRONICS CO., LTD., Suwon-si (KR)

(72) Inventors: Dong-Joo KANG, Hwaseong-si (KR); Tae-Hwan KIM, Hwaseong-si (KR)

(73) Assignee: WORLDEX INDUSTRY & TRADING CO., LTD., Gumi-si (KR)

(21) Appl. No.: 15/191,557

(22) Filed: Jun. 24, 2016

(30) Foreign Application Priority Data
Sep. 23, 2015 (KR) 10-2015-0134559

(51) Int. Cl. H01L 21/683

(52) U.S. Cl. CPC H01L 21/6838

(57) ABSTRACT

A substrate supporter, including a plate; and a plurality of vacuum fins protruding from the plate, each of the vacuum fins having a vacuum hole penetrating through the plate, and each of the vacuum fins including a substrate mounting surface contacting a substrate.

### CROSS-REFERENCE TO RELATED APPLICATION

Korean Patent Application No. 10-2015-0134559, filed on Sep. 23, 2015, in the Korean Intellectual Property Office, and entitled: “Substrate Support Unit and Substrate Treatment Apparatus Comprising the Same,” is incorporated by reference herein in its entirety.

### BACKGROUND

1. Field

Embodiments relate to a substrate support unit and a substrate treatment apparatus including the same.

2. Description of the Related Art

A semiconductor integrated circuit may be a small and thin silicon chip and may include more than tens of millions of electronic components (for example, transistors, diodes, and resistors) fabricated thereon, and the semiconductor integrated circuit may be prepared through various processes including, for example, a photolithography process, an etching process, a deposition process, and a heat treatment process.

### SUMMARY

Embodiments may be realized by providing a substrate supporter, including a plate; and a plurality of vacuum fins protruding from the plate, each of the vacuum fins having a vacuum hole penetrating through the plate, and each of the vacuum fins including a substrate mounting surface contacting a substrate.

The substrate supporter may include a plurality of support fins protruding from the plate. Each of the support fins may include a substrate support surface contacting the substrate.

The substrate mounting surface and the substrate support surface may be on a same plane.

The support fins may be adjacent to an edge of the plate.

The vacuum fins may be along a circle line on the plate.

The circle line may include a first circle line inside the plate, a second circle line enclosing the first circle line, a third circle line enclosing the second circle line, and a fourth circle line adjacent to an edge of the plate and enclosing the third circle line.

The vacuum fins may be equally spaced apart from each other.

The vacuum fins may be along a plurality of linear lines, the linear lines may extend in a first direction, and the linear lines may be parallel to each other.

The plate and the vacuum fins may be made of silicon carbide.

Embodiments may be realized by providing a substrate treatment apparatus, including a chamber including a substrate treatment area; a substrate supporter in the substrate treatment area, the substrate supporter including a plate and a plurality of vacuum fins protruding from the plate, the vacuum fins each having a vacuum hole penetrating through the plate; and a vacuum pump connected to the vacuum hole, each of the vacuum fins including a substrate mounting surface contacting a substrate, and the vacuum pump to create vacuum pressure in the vacuum hole to enable the substrate mounting surface and the substrate to be adsorbed to each other.

The substrate treatment apparatus may further include a plurality of support fins protruding from the plate. Each of the support fins may include a substrate support surface contacting the substrate, and the substrate mounting surface and the substrate support surface may be on a same plane.

The support fins may be adjacent to an edge of the plate.

The vacuum fins may be along a plurality of linear lines, the linear lines may extend in a first direction, and the linear lines may be parallel to each other.

The vacuum fins may be along a circle line on the plate.

The substrate supporter may be made of silicon carbide.

Embodiments may be realized by providing a substrate supporter, including a plate; and fins protruding from the plate, each of the fins including a support surface to support a substrate, a contact area between the substrate and the support surfaces being 0.4% or less of a total area of the substrate.

The fins may include vacuum fins.

An inner surface of each of the vacuum fins may enclose a vacuum hole, and each of the support surfaces may have a width surrounding the vacuum holes ranging from 0.2 mm to 0.4 mm.

Each of the vacuum fins may have a height ranging from 1.0 mm to 1.4 mm.

Each vacuum hole may have a diameter adjacent to the support surface of 3 mm or larger.

### BRIEF DESCRIPTION OF THE DRAWINGS

Features will become apparent to those of skill in the art by describing in detail exemplary embodiments with reference to the attached drawings in which:

FIG. 1 illustrates a schematic top view of the substrate support unit according to some embodiments;

FIG. 2 illustrates a cross-sectional view taken along line A-A of FIG. 1;

FIG. 3 illustrates a schematic cross-sectional view of the substrate support unit according to some embodiments;

FIG. 4 illustrates a schematic top view of the substrate support units according to some embodiments;

FIG. 5 illustrates a cross-sectional view taken along line B-B of FIG. 4;

FIG. 6 illustrates a schematic cross-sectional view of the substrate support unit according to some embodiments;

FIG. 7 illustrates a schematic top view of the substrate support unit according to some embodiments;

FIG. 8 illustrates a schematic top view of the substrate support unit according to some embodiments;

FIG. 9 illustrates a schematic top view of the substrate support unit according to some embodiments;

FIG. 10 illustrates a schematic top view of the substrate support unit according to some embodiments;

FIG. 11 illustrates a schematic top view of the substrate support unit according to some embodiments; and

FIG. 12 illustrates a schematic cross-sectional view of the substrate support unit according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc., may be used herein to describe various elements, these elements should not be limited by these terms. These terms are only used to distinguish one element from another element. Thus, for example, a first element, a first component or a first section discussed below could be termed a second element, a second component or a second section.

The use of the terms “a” and “an” and “the” and similar referents in the context of describing embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of skill in the art. It is noted that the use of any and all examples, or exemplary terms provided herein is intended merely to better illuminate embodiments and is not a limitation on the scope of embodiments unless otherwise specified. Further, unless defined otherwise, all terms defined in generally used dictionaries may not be overly interpreted.

Descriptions on the embodiments will hereinafter be made on the assumption that a substrate support unit is a vacuum chuck. In an embodiment, various types of vacuumed substrate support units may be used.

Descriptions on the embodiments will be made on the assumption that a substrate is a circular wafer. In an embodiment, wafers having various shapes including a quadrangle may be used.

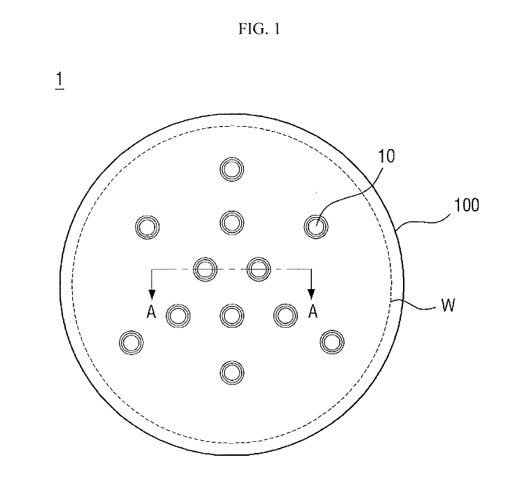

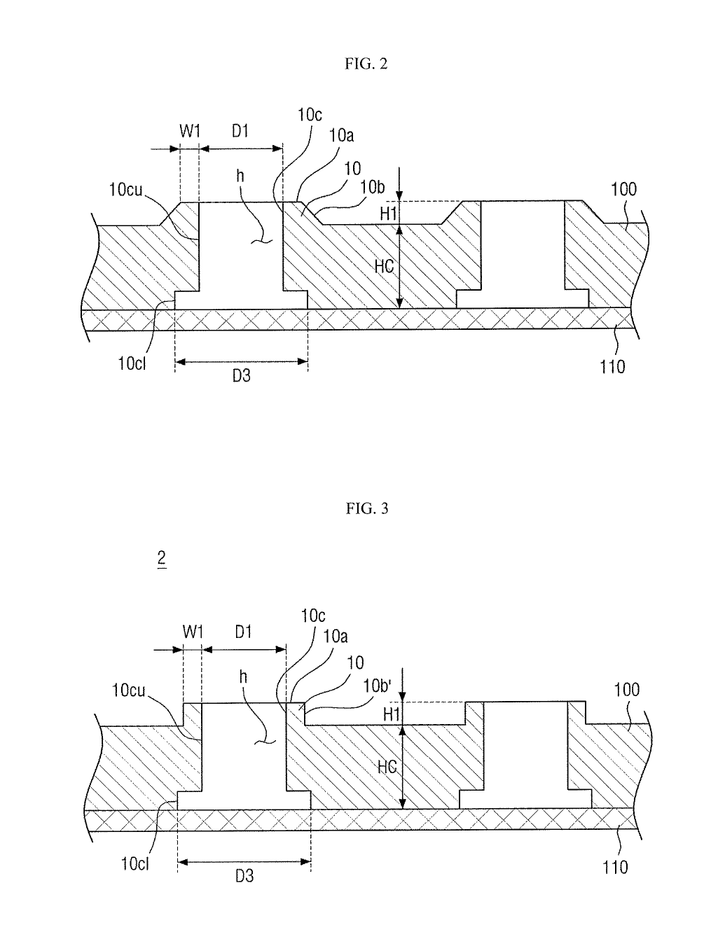

The substrate support unit according to some embodiments will now be described with reference to FIG. 1 and FIG. 2. FIG. 1 illustrates a schematic top view of the substrate support unit according to some embodiments. FIG. 2 illustrates a cross-sectional view taken along line A-A of FIG. 1.

Referring to FIG. 1 and FIG. 2, a substrate support unit 1 may include vacuum fins 10 and a plate 100. A substrate W may be disposed inside the plate 100. For example, in an embodiment, the plate 100 may have a diameter somewhat larger than the diameter of the substrate W.

The vacuum fins 10 may protrude from the top surface of the plate 100. A plurality of vacuum fins 10 may be formed on the plate 100. The present embodiment is illustrated as having, for example, twelve vacuum fins 10 formed on the plate 100. The number of vacuum fins 10 may vary in consideration of the area of the plate 100 on which the vacuum fins 10 are disposed and the diameter of the substrate W disposed on the plate 100. For example, three may be a minimum number of vacuum fins, and increasing the number may increase the likelihood of a particle being between a vacuum fin and the substrate.

The vacuum fins 10 may be spaced apart from each other. The present embodiment is illustrated as having, for example, the vacuum fins 10 high densely arranged inside the plate 100 and less densely arranged outside the plate 100. In an embodiment, the vacuum fins 10 may be arranged to have various density on the top surface of the plate 100.

Each of the vacuum fins 10 may have, for example, a circular shape when viewed from the top surface of the plate 100 as shown in FIG. 1. In an embodiment, each of the vacuum fins 10 may have a polygonal shape including a triangular shape and a quadrangular shape.

The vacuum fin 10 may include a vacuum hole h penetrating through the plate 100. The vacuum hole h may be connected to a pump line of a vacuum pump of a substrate treatment apparatus described later so as to create a vacuum in the vacuum hole h.

The vacuum fin 10 may include a substrate mounting surface 10a, an outer surface 10b interconnecting the substrate mounting surface 10a and the top surface of the plate 100, and an inner surface 10c enclosing the vacuum hole h.

The top surface of the vacuum fin 10 may be the substrate mounting surface 10a, and the substrate W may be mounted on the substrate mounting surface 10a. For example, the substrate mounting surface 10a may directly contact the substrate W so as to support the substrate W during a substrate treatment process for fabricating a semiconductor chip.

For example, the outer surface 10b of the vacuum fin 10 may be inclined, e.g., at a non-orthogonal angle to the top surface of the plate, and the vacuum fin 10 may become wider toward the bottom thereof and may be tapered at the top thereof. This structure may enable the vacuum fin 10 to be maintained structurally stable, and prevent the vacuum fin 10 from being collapsed by the weight of the substrate W supported by the vacuum fin 10. This structure may enable vacuum fins 10 to be easily manufactured.

The inner surface 10c of the vacuum fin 10 may enclose the vacuum hole h. The inner surface 10c may be stepped, e.g., may include n upper inner surface 10cu and a lower inner surface 10c1, and the width of the vacuum hole h disposed within the vacuum fin 10 may not be constant. For example, the upper inner surface 10cu and the lower inner surface 10c1 may both have slopes orthogonal to the top surface of the plate 100, while having different diameters,

Referring to FIG. 2, the substrate mounting surface 10a of the vacuum fin 10 may have a first width W1. The first width W1 may range, for example, from 0.2 mm to 0.4 mm, and may be 0.3 mm in the present embodiment. When the first width W1 ranges from 0.2 mm to 0.4 mm, the vacuum fin 10 may be well processed, and a contact area between the vacuum fin 10 and the substrate W mounted on the substrate mounting surface 10a may be minimized.

The vacuum fin 10 may be in a protruded shape having a first height H1. The first height H1 may range, for example, from 1.0 mm to 1.4 mm, e.g., may be 1.2 mm in the present embodiment. When the first height H1 ranges from 1.0 mm to 1.4 mm, the vacuum fin 10 may be well processed, and the substrate W and the plate 100 may be fully spaced apart from each other.

The vacuum hole h of the vacuum fin 10 may include a first diameter D1 of the upper inner surface 10cu and a third diameter D3 of the lower inner surface 10c1. The first diameter D1 of the vacuum hole h may be the diameter of a vacuum hole h region adjacent to the top surface of the plate 100. The first diameter D1 may be, for example, 3 mm or larger. When the first diameter D1 is 3 mm or more, vacuum pressure suitable for supporting the substrate W may be obtained. For example, when the first diameter D1 is 3 mm, vacuum pressure of −50 Kpa or less may be formed in the vacuum hole h.

The third diameter D3 of the vacuum hole h may be the diameter of the vacuum hole h region adjacent to the bottom surface of the plate 100. The third diameter D3 of the vacuum hole h may be larger than the first diameter D1. The third diameter D3 may partially or completely overlap the substrate mounting surface 10a and may partially or completely overlap the outer surface 10b. The region having the third diameter D3 of the vacuum hole h may be a vacuum line region formed at the bottom surface of the plate 100. For example, vacuum holes h adjacent to each other may be interconnected through the vacuum line.

A plate sealing unit 110 may be disposed on the bottom surface of the plate 100. The plate sealing unit 110 may be separated from the plate 100 or formed integrally with the plate 100. In an embodiment, a substrate support unit may not include plate sealing unit 110.

The substrate support unit 1 may be made of silicon carbide (SiC). Silicon carbide (SiC) may be suitable as a material for forming a substrate support unit of a substrate treatment apparatus due to, for example, excellent mechanical, chemical, thermal, and electrical characteristics thereof. In an embodiment, various types of materials may be used in manufacturing a substrate support unit.

When the substrate support unit 1 is made of silicon carbide (SiC), the protruded shape of the vacuum fin 10 may be obtained by grinding the plate 100 made of silicon carbide (SiC).

The substrate support unit may support the substrate W by means of the substrate mounting surface 10a of the vacuum fin 10 and simultaneously adsorb the substrate W by means of the vacuum hole h, a contact area between the substrate W and the substrate support unit 1 may be minimized and the substrate W may be stably fixed and maintained.

The substrate support unit according to some embodiments will now be described with reference to FIG. 3. FIG. 3 illustrates a schematic cross-sectional view of the substrate support unit according to some embodiments. A substrate support unit 2 according to the present embodiment may be substantially the same as the substrate support unit 1 described with reference to FIG. 1, except that the slope of an outer surface 10b′ of a vacuum fin 10 is vertical to, i.e., orthogonal to, the top surface of the plate 100, identical reference numerals are used to identify identical components, and repeated description of the same component will be omitted. Again, third diameter D3 may partially or completely overlap the substrate mounting surface 10a

Referring to FIG. 3, the substrate support unit 2 may include the vacuum fin 10 and the plate 100. The vacuum fin 10 may include the substrate mounting surface 10a, the outer surface 10b′ and the inner surface 10c, and may also include the vacuum hole h.

The slope of the outer surface 10b′ of the vacuum fin 10 may be the same as, e.g., be parallel to, that of the inner surface 10c of the vacuum fin 10. The outer surface 10b′ of the vacuum fin 10 may face the inner surface 10c of the vacuum fin 10.

In the present embodiment, the slope of the outer surface 10b′ of the vacuum fin 10 may be vertical, e.g., orthogonal, to the top surface of the plate 100. Through this structure, the length of the outer surface 10b may become shortened, and the area of the outer surface 10b may be reduced, further reducing the probability of a particle between the vacuum fin 10 and a substrate.

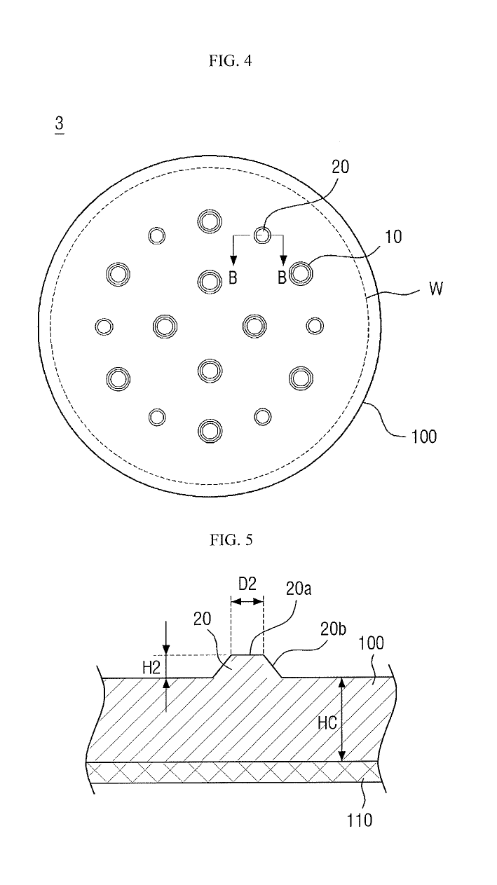

The substrate support unit according to some embodiments will be described with reference to FIG. 4 and FIG. 5. FIG. 4 illustrates a schematic top view of the substrate support units according to some embodiments. FIG. 5 illustrates a cross-sectional view taken along line B-B of FIG. 4.

A substrate support unit 3 according to the present embodiment may be substantially the same as the substrate support unit 1 described with reference to FIG. 1, except that support fins 20 may be further provided, identical reference numerals are used to identify identical components, and repeated description of the same component will be omitted.

The substrate support unit 3 according to the present embodiment may include the plate 100, the vacuum fins 10, and the support fins 20.

Each of the support fins 20 may be in a protruded shape. Each of the support fins 20 may have, for example, a circular shape when viewed from the top surface of the plate 100 as shown in FIG. 4. In an embodiment, each of the support fins 20 may have a polygonal shape including a triangular shape and a quadrangular shape.

A plurality of support fins 20 may be disposed on the plate 100. The support fins 20 may be disposed adjacent to an edge of the plate 100. The support fins 20 may be disposed adjacent to an edge of the substrate W so as to support the edge region of the substrate W.

For example, the support fins 20 may be spaced apart from each other at predetermined spacing.

The support fin 20 may include a substrate support surface 20a and a side surface 20b. The support fin 20 may be in a protruded shape having a second height H2. For example, the distance between the substrate support surface 20a of the support fin 20 and the top surface of the plate 100 may be the second height H2.

The second height H2 may range, for example, from 1.0 mm to 1.4 mm, e.g., may be 1.2 mm in the present embodiment. When the second height H2 ranges from 1.0 mm to 1.4 mm, the support fin 20 may be well processed, and the substrate W and the plate 100 may be fully spaced apart from each other.

The second height H2 of the support fin 20 may be the same as the aforementioned first height H1 of the vacuum fin 10. The substrate support surface 20a of the support fin 20 and the substrate mounting surface 10a of the vacuum fin 10 may be disposed in the same plane.

The substrate support surface 20a of the support fin 20 may have a second width D2. The second width D2 may range, for example, from 1.0 mm to 1.5 mm. When the second width D2 ranges from 1.0 to 1.5 mm, the support fin 20 may be well processed, and a contact area between the support fin 20 and the substrate W disposed on the substrate support surface 20a may be minimized. The side surface 20b of the support fin 20 may be inclined, e.g., at a non-orthogonal angle to the top surface of the plate 100.

The substrate support unit 3 may include support fins 20 disposed, for example, only in a peripheral region adjacent to the edge of the plate 100. This structure may minimize a contact area between the substrate W and the substrate support unit 3 and also prevent an edge of the substrate W from being drooped, e.g., from sagging, and flatness of the substrate W may be improved.

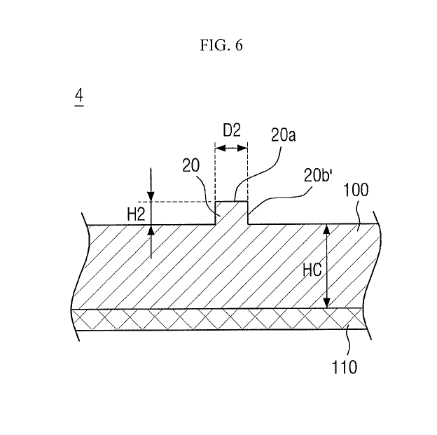

The substrate support unit according to some embodiments will be described with reference to FIG. 6. FIG. 6 illustrates a schematic cross-sectional view of the substrate support unit according to some embodiments. A substrate support unit 4 according to the present embodiment may be substantially the same as the substrate support unit 3 described with reference to FIG. 4, except for the slope of a side surface 20b′ of the support fin 20, identical reference numerals are used to identify identical components, and repeated description of the same component will be omitted.

Referring to FIG. 6, the support fin 20 may include the substrate support surface 20a and the side surface 20b′. The side surface 20b′ may have a slope vertical, to, e.g., orthogonal to, the top surface of the plate 100.

In the present embodiment, the support fin 20 may include the side surface 20b′ having a slope that is vertical to the top surface of the plate 100, and the length of the side surface 20b may become shortened and the area of the side surface 20b may be minimized.

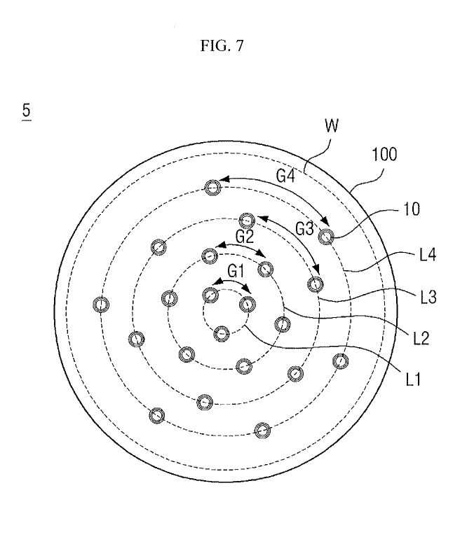

The substrate support unit according to some embodiments will be described with reference to FIG. 7. FIG. 7 illustrates a schematic top view of the substrate support unit according to some embodiments. A substrate support unit 5 according to the present embodiment may be substantially the same as the substrate support unit 1 described with reference to FIG. 1, except for the number and arrangement of vacuum fins 10, identical reference numerals are used to identify identical components, and repeated description of the same component will be omitted.

Referring to FIG. 7, the substrate support unit 5 may include the plate 100 and the vacuum fins 10. The vacuum fins 10 may be disposed on the plate 100.

The vacuum fins 10 may be disposed in plural numbers, e.g., there may be a plurality of vacuum fins 10, and the vacuum fins 10 may be disposed along circle lines L1, L2, L3, and L4, e.g., along different radii of the substrate support unit 5.

In the present embodiment, the circle lines L1, L2, L3, and L4 are virtual lines for illustrating an arrangement of the vacuum fins 10. The circle lines L1, L2, L3, and L4 do not physically exist on the plate 100, but are depicted as dotted lines on the drawing for ease of understanding.

For example, the circle lines may include a first circle line L1, a second circle line L2, a third circle line L3, and a fourth circle line L4. In an embodiment, the number of circle lines may decrease or increase in consideration of the number of the vacuum fins 10 to be disposed on the plate 100.

The first circle line L1 may be adjacent a central region of the plate 100. For example, three vacuum fins 10 may be disposed along the first circle line L1. The vacuum fins 10 may be disposed along the first circle line L1 such that a first gap G1 is provided between each vacuum fin 10 and other vacuum fin 10 placed adjacent thereto.

The second circle line L2 may enclose the first circle line L1. For example, six vacuum fins 10 may be disposed along the second circle line L2. The vacuum fins 10 may be disposed along the second circle line L2 such that a second gap G2 is provided between each vacuum fin 10 and other vacuum fin 10 placed adjacent thereto.

The third circle line L3 may enclose the second circle line L2. For example, six vacuum fins 10 may be disposed along the third circle line L3. The vacuum fins 10 may be disposed along the third circle line L3 such that a third gap G3 is provided between each vacuum fin 10 and other vacuum fin 10 placed adjacent thereto.

The fourth circle line L4 may enclose the third circle line L3. For example, six vacuum fins 10 may be disposed along the fourth circle line L4. The vacuum fins 10 may be disposed along the fourth circle line L4 such that a fourth gap G4 is provided between each vacuum fin 10 and other vacuum fin 10 placed adjacent thereto.

The first to fourth circle lines L1, L2, L3, and L4 may be equally spaced apart from each other along a radius from the center of the plate 100. Spacing between vacuum fins 10 on the circle line may increase away from the center of the plate 100.

For example, twenty-one vacuum fins 10 are depicted as being disposed along the first to fourth circle lines L1, L2, L3, and L4 in the present embodiment. The number of vacuum fins 10 disposed along the circle lines may be determined in consideration of various elements such as the number of circle lines, the area of the plate 100 and the area of the substrate W supported by the substrate support unit 5.

The vacuum fins 10 of the substrate support unit 5 according to the present embodiment may be disposed along the circle lines. When the plate 100 and the substrate W disposed on the plate 100 are in a circular shape, the vacuum fins 10 may be disposed in a further efficient manner in consideration of the area of the substrate W, and the substrate W may be more stably supported using an appropriate number of vacuum fins 10 determined in consideration of the shape of the substrate W.

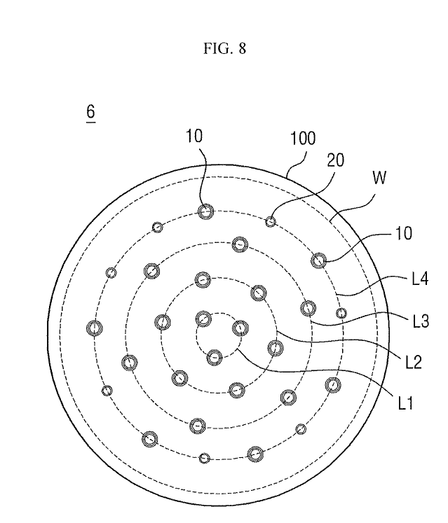

The substrate support unit according to some embodiments will be described with reference to FIG. 8. FIG. 8 illustrates a schematic top view of the substrate support unit according to some embodiments. A substrate support unit 6 according to the present embodiment may be substantially the same as the substrate support unit 5 described with reference to FIG. 7, except that the substrate support unit 6 may further include the support fins 20. The substrate support unit 6 according to the present embodiment may be substantially the same as the substrate support unit 3 described with reference to FIG. 4 and FIG. 5 except for the number and arrangement of the support fins 20, identical reference numerals are used to identify identical components, and repeated description of the same component will be omitted.

Referring to FIG. 8, the substrate support unit 6 may include the plate 100, vacuum fins 10, and support fins 20. The vacuum fins 10 and the support fins 20 may be disposed on the plate 100.

The support fins 20 may be disposed in plural numbers, e.g., there may be a plurality of support fins 20, and the support fins 20 may be disposed along the fourth circle line L4. The plurality of support fins 20 may be spaced apart from each other at a predetermined spacing along the fourth circle line L4. The support fins 20 may be interposed between the vacuum fins 10 along the fourth circle line L4.

In the present embodiment, seven support fins 20 and twenty-one vacuum fins 10, for example, are depicted as being disposed on the plate 100.

In the present embodiment, the support fins 20 of the substrate support unit 6 may be disposed adjacent to the edge of the plate 100, and flatness of the substrate W may be improved while minimizing a contact area between the substrate W and the substrate support unit 6.

In the present embodiment, when the substrate W is a 200 mm wafer, a contact area between the substrate W and the substrate mounting surface 10a of the vacuum fin 10 and between the substrate W and the substrate support surface 20a of the support fin 20 may be 0.4% or less, for example, 0.39% of the total area of the substrate W.

The difference between the maximum value and minimum value of the flatness of the substrate W may be measured as 1.24 μm on the basis of zero, which means complete flatness, and flatness of the substrate W may be determined to be good.

For example, the substrate support unit 6 may maintain good flatness of the substrate W and minimize the contact area between the substrate W and the substrate support unit 6 by using the support fins 20 disposed at the edge of the plate 100 and vacuum fins 10 disposed along the circle lines.

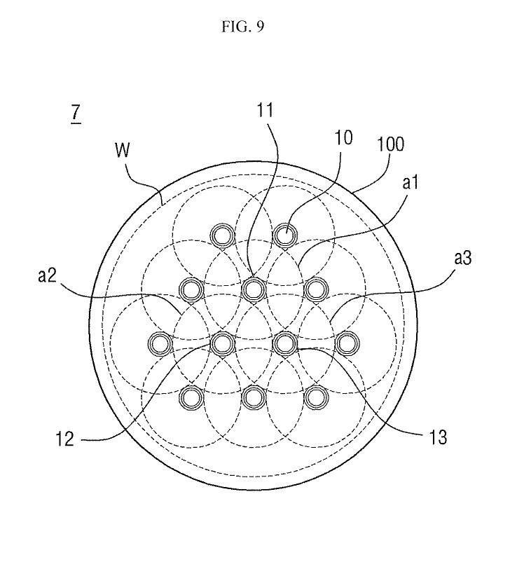

The substrate support unit according to some embodiments will be described with reference to FIG. 9. FIG. 9 illustrates a schematic top view of the substrate support unit according to some embodiments. A substrate support unit 7 according to the present embodiment may be substantially the same as the substrate support unit 1 described with reference to FIG. 1, except for an arrangement of the vacuum fins 10, identical reference numerals are used to identify identical components, and repeated description of the same component will be omitted.

Referring to FIG. 9, the substrate support unit 7 may include the plate 100 and the vacuum fins 10. The vacuum fins 10 may be disposed on the plate 100, and may include a first vacuum fin 11, a second vacuum fin 12 and a third vacuum fin 13.

The first vacuum fin 11, the second vacuum fin 12, and the third vacuum fin 13 are used herein to describe the arrangement of the vacuum fins 10, and the vacuum fins 10 of the present embodiment may be substantially the same as the vacuum fins 10 described in the aforementioned embodiments.

The first vacuum fin 11 may be disposed in a first region a1 indicated by a dotted line, the second vacuum fin 12 may be disposed in a second region a2 indicated by a dotted line, and the third vacuum fin 13 may be disposed in a third region a3 indicated by a dotted line. For example, the vacuum fins 11 to 13 may form an equilateral triable with respect to a center of the plate 100. The first to third regions may encompass a circle having a radius equal to the spacing between the first to third vacuum fins 11 to 13.

The first vacuum fin 11 may be disposed at the center point of the first region a1, the second vacuum fin 12 may be disposed at the center point of the second region a2, and the third vacuum fin 13 may be disposed at the center point of the third region a3. The first vacuum fin 11, the second vacuum fin 12, and the third vacuum fin 13 may be equally spaced apart from each other.

Meanwhile, the area of each of the first region a1, the second region a2 and the third region a3 may be the same, and a single vacuum fin 10 may be formed in each same area.

For example, the substrate support unit 7 according to the present embodiment may be configured in that one vacuum fin 10 may be disposed in each of the regions in consideration of the area of the plate 100. For example, the vacuum fins 10 may be disposed on the plate 100 in consideration of the vacuum pressure, support force and the like of one vacuum fin 10, and appropriate adsorption force may be maintained between the substrate W and the vacuum fins 10 even when wafers of various sizes are provided as substrates W.

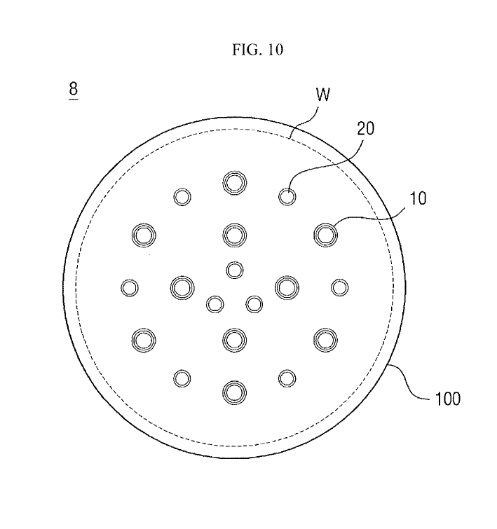

The substrate support unit according to some embodiments will be described with reference to FIG. 10. FIG. 10 illustrates a schematic top view of the substrate support unit according to some embodiments. A substrate support unit 8 according to the present embodiment may be substantially the same as the substrate support unit 3 described with reference to FIG. 4, except for an arrangement of the support fins 20, identical reference numerals are used to identify identical components, and repeated description of the same component will be omitted.

Referring to FIG. 10, the substrate support unit 8 may include the plate 100, vacuum fins 10, and support fins 20. The vacuum fins 10 and the support fins 20 may be disposed on the plate 100.

When the substrate support unit 8 according to the present embodiment is compared with the aforementioned embodiments, the support fins 20 may be disposed in the region adjacent to the edge of the plate 100, as in FIG. 4, and also in the center region of the plate 100. For example, three support fins 20 may form an equilateral triangle with respect to the center region of the plate 100.

The substrate support unit 8 according to the present embodiment may improve flatness of the substrate W disposed on the plate 100.

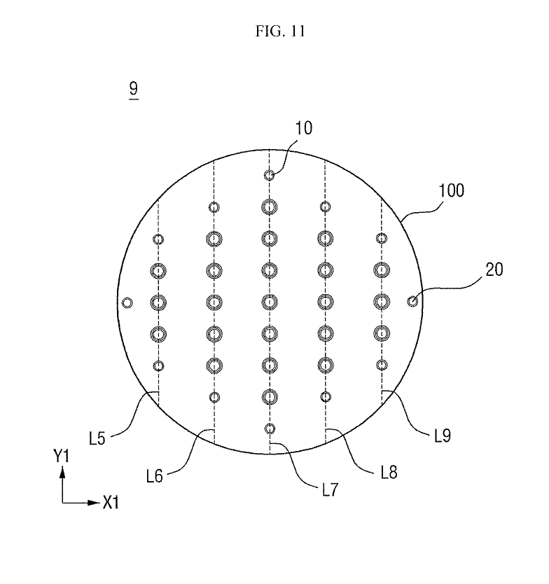

The substrate support unit according to some embodiments will be described with reference to FIG. 11. FIG. 11 illustrates a schematic top view of the substrate support unit according to some embodiments. A substrate support unit 9 according to the present embodiment may be substantially the same as the substrate support unit 6 described with reference to FIG. 8, except for an arrangement of the vacuum fins 10 and the support fins 20, identical reference numerals are used to identify identical components, and repeated description of the same component will be omitted.

Referring to FIG. 11, the substrate support unit 9 may include the plate 100, vacuum fins 10, and support fins 20.

In the present embodiment, the vacuum fins 10 and the support fins 20 may be disposed along linear lines on the plate 100.

The linear line may include fifth to ninth linear lines L5, L6, L7, L8, and L9. Each of the fifth to ninth linear lines L5, L6, L7, L8, and L9 may extend in a first direction Y1, and may be in parallel to each other in a second direction X1.

In the present embodiment the fifth to ninth linear lines L5, L6, L7, L8, and L9 are virtual lines for illustrating an arrangement of the vacuum fins 10 and the support fins 20. The fifth to ninth linear lines L5, L6, L7, L8, and L9 do not physically exist on the plate 100, but are depicted as dotted lines on the drawing for ease of understanding.

For example, two support fins 20 may be disposed at the start and end of the fifth linear line L5 and three vacuum fins 10 may be interposed between the two support fins 20 along the fifth linear line L5, two support fins 20 may be disposed at the start and end of the sixth linear line L6 and five vacuum fins 10 may be interposed between the two support fins 20 along the sixth linear line L5, two support fins 20 may be disposed at the start and end of the seventh linear line L7 and seven vacuum fins 10 may be interposed between the two support fins 20 along the seventh linear line L7, two support fins 20 may be disposed at the start and end of the eighth linear line L8 and five vacuum fins 10 may be interposed between the two support fins 20 along the eighth linear line L8, and two support fins 20 may be disposed at the start and end of the ninth linear line L9 and three vacuum fins 10 may be interposed between the two support fins 20 along the ninth linear line L9.

The number of the vacuum fins 10 and the support fins 20 disposed along the fifth to ninth linear lines L5, L6, L7, L8, and L9 may vary in consideration of the area of the substrate supported by the substrate support unit 9.

For example, the vacuum fins 10 and the support fins 20 may be disposed on the fifth to ninth linear lines L5, L6, L7, L8, and L9 symmetrically to each other about the central seventh linear line L7. The fifth to ninth linear lines L5 to L9 may be evenly spaced from one another and the vacuum fins along each line may be evenly spaced from one another, e.g., the vacuum fins may be evenly spaced in a direction between the linear lines.

In the present embodiment, the vacuum fins 10 and the support fins 20 of the substrate support unit 9 may be disposed on linear lines in consideration of the area of the plate 100, and an arrangement of the vacuum fins 10 and the support fins 20 may be appropriately designed in correspondence to the substrate including wafers having various sizes.

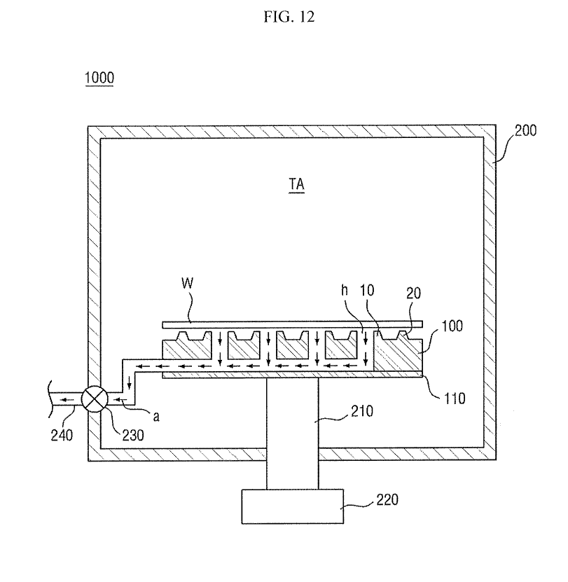

The substrate treatment device according to some embodiments will be described with reference to FIG. 12. FIG. 12 illustrates a schematic cross-sectional view of the substrate support unit according to some embodiments.

Referring to FIG. 12, a substrate treatment apparatus 1000 may include a chamber 200, a support 210, a base 220, a vacuum pump 230 and a pump line 240. The substrate treatment apparatus 1000 may include a substrate support unit for supporting the substrate W. The substrate support unit may include the plate 100, vacuum fins 10, e.g., the vacuum fins 10 may form rows, support fins 20, and the plate sealing unit 110, and may be any one of the substrate support units 1, 2, 3, 4, 5, 6, 7, 8, and 9 according to the aforementioned embodiments or a combination thereof, and descriptions of the substrate support unit and the plate 100, the vacuum fins 10, the support fins 20, and the plate sealing unit 110 of the substrate support unit will be omitted.

The chamber 200 of the substrate treatment apparatus 1000 may include a substrate treatment area TA formed therein so as to treat the substrate W. The substrate treatment apparatus 1000 may include a cover for exposing outwardly the substrate treatment area TA of the chamber 200, and a passage for enabling the substrate W to be carried into or from the chamber 200.

The chamber 200 may include a temperature measuring unit for measuring the temperature of the substrate treatment area TA, and the substrate treatment apparatus 1000 may further include various components depending on the type thereof.

For example, the substrate treatment apparatus 1000 may perform various types of manufacturing processes including a photolithography process, an etching process, a deposition process and a heat treatment process, and when the substrate treatment apparatus 1000 uses plasma, the substrate treatment apparatus 1000 may further include a plasma supply unit, a gas supply unit, a gas exhaust unit, a pressure reduction unit, electrodes for generating plasma, a focus ring for concentrating plasma to a substrate and a heating unit.

The substrate support unit and the plate 100, the vacuum fins 10, the support fins 20, and the plate sealing unit 110 of the substrate support unit may be connected to the base 220 through the support 210. The substrate support unit may be fixed on the ground through the support 210 and the base 220.

In the present embodiment, the substrate support unit is depicted as being, for example, directly connected to the support 210. In an embodiment, additional components may be interposed between the substrate support unit and the support 210.

The vacuum pump 230 may create vacuum pressure in the vacuum hole h by using the pump line 240 connected to the vacuum hole h. For example, air (a) existing in the vacuum hole h may pass through the pump line 240 along the direction indicated by an arrow and be discharged to outside through the vacuum pump 230, and an adsorption using vacuum may be created between the substrate W and the vacuum fins 10.

In the present embodiment, the substrate W is depicted as being, for example, somewhat spaced apart from the vacuum fins 10 and the support fins 20. In an embodiment, the substrate W and the vacuum fins 10 and the support fins 20 may contact each other.

By way of summation and review, a silicon monocrystalline ingot may be cut into a thickness of hundreds of micrometers (μm) and one surface thereof may be polished like a mirror so as to produce a silicon wafer, and a semiconductor integrated circuit may be formed on the silicon wafer.

To perform a stable semiconductor fabrication process, a wafer may need to be properly fixed during the semiconductor fabrication process. As a substrate support unit for fixing or transferring a wafer, a mechanical chuck, an electrostatic chuck, or a vacuum chuck may be used.

A mechanical chuck may have an arm or a clamp for pressing a wafer against a support surface, an electrostatic chuck may generate a voltage difference between a wafer and a metal electrode or between pairs of electrodes and may allow the wafer and the electrodes to be separated from each other by a dielectric layer, and a vacuum chuck may enable the wafer to be stably adsorbed by vacuum pressure. Dust, foreign substances, or by-products (hereinafter, referred to as “particles”) generated during a substrate treatment process for fabricating a semiconductor chip may contaminate a mounting surface of a substrate support unit on which a wafer may be mounted. When the wafer is mounted on the contaminated mounting surface of the substrate support unit, defocus may occur, and serious losses in producing semiconductors may be caused.

A probability of occurrence of defocus may be lowered by minimizing a contact area between a wafer and a substrate support unit, and a substrate treatment process for fabricating a semiconductor chip may have improved reliability.

Embodiments may provide a substrate support unit capable of improving reliability of a substrate treatment process for fabricating a semiconductor chip. Embodiments may provide a substrate support unit with a minimized contact area between the substrate support unit and a substrate. Embodiments may provide a substrate support unit of a substrate treatment apparatus capable of increasing flatness of a substrate and stably adsorbing the substrate on a substrate mounting surface while minimizing a contact area between the substrate support unit and the substrate. Embodiments may provide a substrate treatment apparatus including the substrate support unit described above.

Embodiments relate to a substrate treatment unit using vacuum and a substrate treatment apparatus including the same.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate supporter, comprising:
a plate; and
a plurality of vacuum fins protruding from the plate,
each of the vacuum fins having a vacuum hole penetrating through the plate, and
each of the vacuum fins including a substrate mounting surface contacting a substrate.

2. The substrate supporter as claimed in claim 1, further comprising a plurality of support fins protruding from the plate,
wherein each of the support fins includes a substrate support surface contacting the substrate.

3. The substrate supporter as claimed in claim 2, wherein the substrate mounting surface and the substrate support surface are on a same plane.

4. The substrate supporter as claimed in claim 2, wherein the support fins are adjacent to an edge of the plate.

5. The substrate supporter as claimed in claim 1, wherein the vacuum fins are along a circle line on the plate.

6. The substrate supporter as claimed in claim 5, wherein the circle line includes a first circle line inside the plate, a second circle line enclosing the first circle line, a third circle line enclosing the second circle line, and a fourth circle line adjacent to an edge of the plate and enclosing the third circle line.

7. The substrate supporter as claimed in claim 1, wherein the vacuum fins are equally spaced apart from each other.

8. The substrate supporter as claimed in claim 1, wherein:
the vacuum fins are along a plurality of linear lines,
the linear lines extend in a first direction, and
the linear lines are parallel to each other.

9. The substrate supporter as claimed in claim 1, wherein the plate and the vacuum fins are made of silicon carbide.

10. A substrate treatment apparatus, comprising:
a chamber including a substrate treatment area;
a substrate supporter in the substrate treatment area, the substrate supporter including a plate and a plurality of vacuum fins protruding from the plate, the vacuum fins each having a vacuum hole penetrating through the plate; and
a vacuum pump connected to the vacuum hole,
each of the vacuum fins including a substrate mounting surface contacting a substrate, and
the vacuum pump to create vacuum pressure in the vacuum hole to enable the substrate mounting surface and the substrate to be adsorbed to each other.

11. The substrate treatment apparatus as claimed in claim 10, further comprising a plurality of support fins protruding from the plate,
wherein each of the support fins includes a substrate support surface contacting the substrate, and the substrate mounting surface and the substrate support surface are on a same plane.

12. The substrate treatment apparatus as claimed in claim 11, wherein the support fins are adjacent to an edge of the plate.

13. The substrate treatment apparatus as claimed in claim 10, wherein:
the vacuum fins are along a plurality of linear lines,
the linear lines extend in a first direction, and
the linear lines are parallel to each other.

14. The substrate treatment apparatus as claimed in claim 10, wherein the vacuum fins are along a circle line on the plate.

15. The substrate treatment apparatus as claimed in claim 10, wherein the substrate supporter is made of silicon carbide.

16. A substrate supporter, comprising:
a plate; and
fins protruding from the plate, each of the fins including a support surface to support a substrate,
a contact area between the substrate and the support surfaces being 0.4% or less of a total area of the substrate.

17. The substrate supporter as claimed in claim 16, wherein the fins include vacuum fins.

18. The substrate supporter as claimed in claim 17, wherein:
an inner surface of each of the vacuum fins encloses a vacuum hole, and
each of the support surfaces has a width surrounding the vacuum holes ranging from 0.2 mm to 0.4 mm.

19. The substrate supporter as claimed in claim 18, wherein each of the vacuum fins has a height ranging from 1.0 mm to 1.4 mm.

20. The substrate supporter as claimed in claim 19, wherein each vacuum hole has a diameter adjacent to the support surface of 3 mm or larger.
